(19) United States
(12) Patent Application Publication
(10) Pub. No.: US 2005/0135095 A1
(43) Pub. Date: Jun. 23, 2005

(54) Array for the illumination of an object

(76) Inventor: Enrico Geissler, Jena (DE)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(21) Appl. No.: 11/016,559

(22) Filed: Dec. 17, 2004

(30) Foreign Application Priority Data
Dec. 19, 2003 (DE) 103 59 753.0

(51) Int. Cl. H01S 5/00

(52) U.S. Cl. 362/231

(57) ABSTRACT

An array for the illumination of an object, preferably a microdisplay, by means of a two-dimensional array of individual emitters, the focal wavelengths of which correspond, respectively to the primary colors red, green and blue, and an apparatus for the spatial superimposition of the light components. The invention is characterized in that a first two-dimensional array of individual emitters and a second two-dimensional arrays of individual emitters are provided, the light components of which are spatially combined by means of a beam splitter, and the first two-dimensional array of individual emitters transmits two spectral ranges, each having a focal point wavelength, wherein the output components of the at least three light components are dimensioned in such a way that the spatially superimposed light components produce white illumination light.

### FIELD OF THE INVENTION

The invention relates to an array for the illumination of an object, preferably a microdisplay, by means of a two-dimensional array of individual emitters, the focal point wavelengths of which correspond, respectively to the primary colors red, green and blue, and an apparatus for the spatial superimposition of the light components.

### BACKGROUND OF THE INVENTION

An illumination unit which operates with a plurality of two-dimensionally extended light sources (e.g., LEDs) is known from WO99/64912 A1 for use in projectors. The light components from three LED arrays, in the colors red, green and blue, are combined by a dichroitic prism and supplied to an LCD display.

A disadvantage of the use of prisms to combine beams is that the dichroitic layers used are embedded in glass and adhesive cement, a jump in the refractive index from glass to air does not occur and, as a result, less performance is achieved than in the case of a jump in the refractive index against air. The embedded dichroitic layers exhibit a higher splitting of the s and p components, at the same level of complexity, and greater edge shift across the angle of incidence than layered systems that operate against air.

It is also known, from Habers, G., Paolini, S., Keuper, M:. “Performance of High-Power LED Illuminators in Projection Displays” 2003 International SID Symposium, to effect the combination of beams alternatively through dichroitic mirrors in the form of sequentially place panels or two intersecting glass panels, each of which is provided with dichroitic layers.

Two panels connected in series require greater installation space and exhibit disadvantageously different differences in distance from the sources to the connection to the projection device. FIG. 1 shows the schematic structure of such a projector. The light from an LED R and the light from an LED G are combined through a first dichroitic mirror Sp1. The light of an LED B is superimposed over this light through a second dichroitic mirror Sp2. The light reaches a DMD matrix DMD to be illuminated through a lens array LA, a condenser lens KL, a splitter mirror Sp3, and a field lens FL. The light reflected by the DMD matrix to form an image reaches the projection lens OK through the splitter mirror Sp3.

Another depicted solution involving intersecting panels is highly complex in terms of mechanical mounting and, furthermore, exhibits a disadvantageous residual gap in the beam path.

The goal of the invention is to provide an efficient and comparatively simple array for the illumination of an object. The mechanical array is to be comparatively simple. The illumination array is to exhibit a small installation space and achieve equally long distances between all light sources and the connection to the unit to be illuminated. An adjustment of the required output components of the light sources, which exhibit different spectral characteristics, is to be achieved.

### SUMMARY OF THE INVENTION

This goal is achieved, according to the invention, in that a first two-dimensional array of individual emitters and a second two-dimensional array of individual emitters are provided, the light components of which are spatially combined by means of a beam splitter, and at least the first two-dimensional array of individual emitters transmits two spectral ranges, each having a focal point wavelength, wherein the output components of the at least three light components are dimensioned in such a way that the spatially superimposed light components produce white illumination light. A two-dimensional array of individual emitters means that the individual emitters are arranged to be distributed on a surface, or substrate. In this regard, however, each individual emitter is a three-dimensional object.

The invention satisfies the requirement that, in illumination systems, a balanced optical output in the three color channels, red, green and blue, is necessary to generate white light. The efficiency and, therefore, the outputs of the corresponding three individual emitters, red, green and blue differs by several factors, so that the number of individual emitters, especially in the case of LEDs or laser diodes, differs in the individual colors.

However, other color combinations can also be used in connection with the invention, such as yellow, cyan and magenta, and/or others.

The two-dimensional arrays of individual emitters are preferably two-dimensionally extended organic LEDs, luminous diodes, luminescent diodes and/or laser diodes. The individual emitters are preferably arranged in one plane, in the form of a matrix. However, the individual emitters can also be other actively light-emitting components, as well as components arranged in multiple planes and/or in annular form.

Each of the two-dimensional arrays of individual emitters forms a module, wherein a first module contains at least one blue individual emitter as well as at least one red individual emitter, and the second module contains at least one green individual emitter.

Preferably, one module contains four green individual emitters and the other module contains two blue individual emitters and two red individual emitters. The red and blue individual emitters are preferably each arranged diagonally opposite one another. As a result, effective homogeneity of the illumination of the object is easily ensured. Other combinations of the individual colored individual emitters in one module are possible, depending on the available performance classes of individual emitters in the individual colors. In addition, the number of individual emitters in each of the modules can be identical or different, and a module can contain fewer than four or more than four individual emitters.

Furthermore, the use of only one dichroitic beam splitter is required to combine the light components, although this beam splitter must exhibit a band-pass characteristic corresponding to the combination of individual emitters on the two modules. In particular, the dichroitic beam splitter consists of a supporting panel, preferably glass, which carries a dichroitic layer against air (high jump in refractive index).

The invention is given an advantageous form in that one of the two-dimensional arrays of individual emitters transmits a further spectral range having a focal point wavelength of about 488 nm, which corresponds to the color turquoise. A fourth wavelength allows for the illumination of objects with greater color space. This effect is especially desirable for the depiction of images.

An advantageous embodiment consists in the beam splitter being a dichroitic beam splitter or a polarizing beam splitter. In the latter case, the light from one channel is preferably s-polarized and the light from the other channel is preferably p-polarized and combined. However, other components that spatially combine a plurality of differently colored luminous beams can also be used.

The light from the two-dimensional array of individual emitters, the light component of which limits output, is preferably capable of being bunched through a reflective side of the dichroitic beam splitter. Because it is not necessary for these light components to pass through the carrier (glass panel) of the dichroitic beam component, bunching efficiency is better than for the light components of other colors that pass through the beam splitter in transmission.

### BRIEF DESCRIPTION OF THE DRAWINGS

In the following, the invention will be explained in greater detail using figures:

FIG. 1 shows an array for the illumination of a DMD matrix in accordance with the state of the art,

FIG. 2 shows an array for the illumination of an object in accordance with the invention,

FIG. 3 shows an array of an LED illumination having four individual emitters each (R-G-B),

FIG. 4 shows an array of an LED illumination having four individual emitters each (R-G-T-B),

FIG. 5 shows an array of an LED illumination having different numbers of individual emitters (R-G-T-B),

FIG. 6 shows the transmission progression of a dichroitic beam splitter for an array according to FIG. 2,

FIG. 7 shows spectra of the LED for an array according to FIG. 2 and 6,

FIG. 8 shows a projector with LED illumination (R-G-T-B),

FIG. 9 shows the transmission progression of a dichroitic beam splitter for an array according to FIG. 8,

FIG. 10 shows the illumination of an object for microscopic viewing, and also

FIG. 11 shows the transmission progression of a dichroitic beam splitter for an array according to FIG. 10.

### DETAILED DESCRIPTION OF THE INVENTION

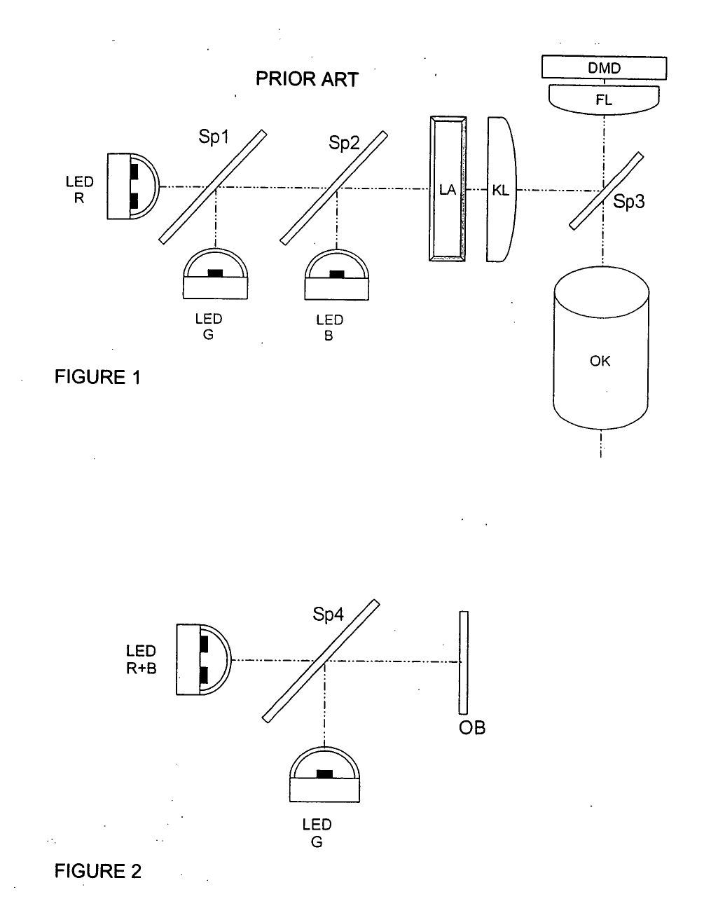

FIG. 1 shows an array for illumination based on the example of a project having a DMD matrix, as was initially described as the state of the art.

FIG. 2 shows a two-dimensional array of individual emitters, which, in the example, are divided into two LED modules, LED R+B and LED G, the emitted light components of which are spatially superimposed through a dichroitic beam splitter Sp4. The superimposed light components are used to illuminate an object OB.

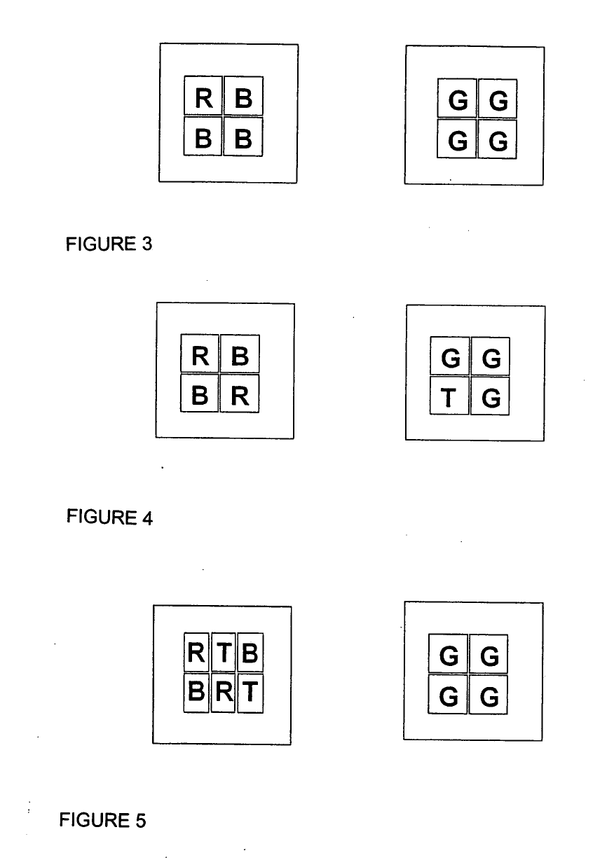

A first LED module LED R+B contains three individual emitters for the color blue and one individual emitter for the color red. A second LED module LED G contains four individual emitters for the color green (see FIG. 3). An example of the output ratios of currently available LEDs for red: green: blue is 6:1:2. Green is the limiting color channel. While retaining the balanced output performance for generating white light, three blue emitters and one red emitter are used in one module. This results in two LED modules having three colors in suitable output classes, which generate output components in each of four individual emitters at a ratio of red: green: blue=4.5:4:2. The modulation of the luminous diodes to generate white of the normal light type D 65 (for example, output components corresponding to the focal point wavelengths of: 100% red, 97% green, 67% blue) then comprises 69% for the one red LED, 100% for the four green LEDs, and 46% for the one blue LED. In this combination, green is the color that limits output.

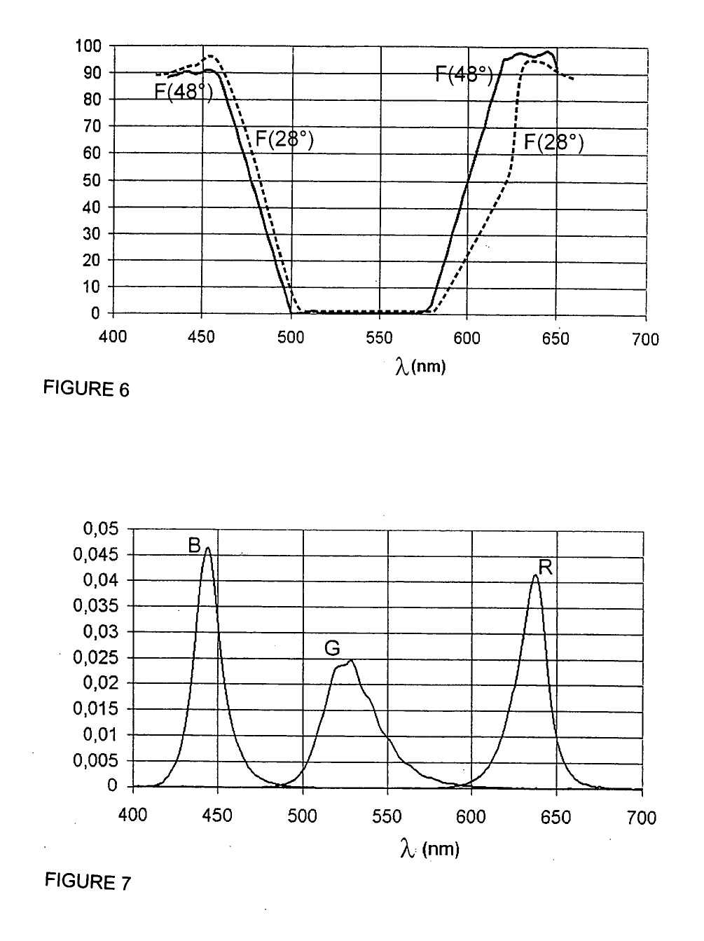

The light of the green LED module is superimposed over the light of the LED module having the two-colored emitters LED R-B through the dichroitic beam splitter Sp4 (on a glass panel as carrier) having a band-pass characteristic FF, which is shown in FIG. 6, and supplied to the object OB to be illuminated. Only this single dichroitic beam splitter Sp4 is required to combine the three colors. F (26′) and F (48′) are the characteristics for a dispersion cone of the individual emitters of +/−10″. All emitters are disposed at a virtually identical distance from the bunching site, which lies in the plane of the beam splitter Sp4 (the dimensional relationships shown in FIG. 2 do not correspond to actual conditions. In practice, the two-dimensional expansion of the modules having the individual emitters corresponds in size to the thickness of the beam splitter.)

FIG. 7 shows the relative intensity of the differently colored LEDs across the wavelength in planar-scaled form. The light of the green LED module (in this case, the color that limits output) is advantageously supplied through the reflective side of the dichroitic beam splitter Sp4, because, in this case, no aberrations occur as the light passes through the glass panel. The dichroitic beam splitter is more efficient in reflection than in transmission.

In addition, the band-pass characteristic of the dichroitic beam splitter Sp4 can be influenced by means of its angle relative to the beam paths of the individual emitters.

FIG. 5 shows, as an example, another array of individual emitters. Here, in addition to the individual emitters that emit the three primary colors, red, green and blue, a fourth type of individual emitter is used which emits the color turquoise with, for example, a focal point wavelength of 488 nm. FIG. 4 shows two LED modules, each having four individual emitters, of which one module carries the individual emitters for the colors red and blue and another module the individual emitters for the colors green and turquoise. The dichroitic beam splitter Sp4 filter must exhibit a correspondingly suitable characteristic F, which is shown in FIG. 9 in relation to the spectral emission of the light sources. In the example, the band edge of the dichroitic beam splitter Sp4 for combining blue and turquoise is relatively steep.

The following combination of individual emitters is used in the example shown in FIG. 4:

| | Rated output of the | Number of | Rated output |
|---|---|---|---|
| Color of | individual emitter in | individual emitters | of a color |
| the LED | Watts (opt.) | (LED) | in Watts (opt.) |
| Red | 6 | 1 | 6 |
| Green | 1 | 3 | 3 |
| Blue | 2 | 3 | 6 |
| Turquoise | 2 | 1 | 2 |

To generate white of the normal light type D 65 (output components correspond to: 100% red, 86% green, 88% blue and 59% turquoise), the LED of the color red is modulated at a maximum of 56% (3.4 Watts), the three LEDs with the color green at a maximum of 97% (2.9 Watts), the three LEDs with the color Blue at a maximum of 75% (3 Watts), and the LED with the color turquoise at a maximum of 100% (2 Watts) of the rated output. In this example, turquoise is the color that limits the output. By means of suitable output dimensioning of the LEDs, as well as by means of advantageous combination of the number as well as the array of the individual emitters on two separate modules containing these individual emitters, output optimization can be performed so that as many of the individual emitters as possible are operated close to their respective rated outputs, e.g., at 80%. Such operation below rated output also ensures prolonged serviceable life of the individual emitters.

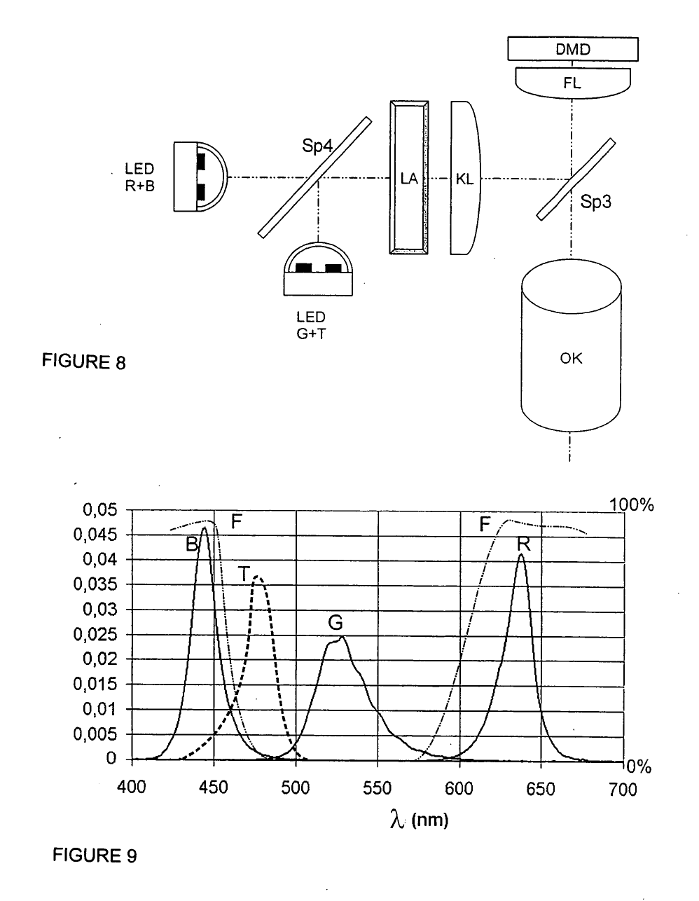

FIG. 8 shows the use of the LED module in accordance with FIG. 4 in a projector. The light of the LEDs, spatially superimposed and combined by means of the dichroitic beam splitter Sp4, is supplied to the projection system in chronological sequence for modulation. To this end, both a light mixing rod and a lens array are possible as coupling sites. In the example shown in FIG. 8, the light reaches the DMD matrix DMD to be illuminated through the lens array LA, the condenser lens KL, the splitter mirror Sp3, and the field lens FL. The light reflected by the DMD matrix to form the image reaches the projection lens OK through the splitter mirror Sp3. Here, the DMD matrix DMD is the illuminated object OK. Depending on the selection of duration of the chronological sequences for the individual colors, the output distribution described above must be adjusted to the individual colors so that a white image can be generated.

In the example shown in FIG. 5, one LED module carries six individual emitters, two red R, two blue B and two turquoise T. The other LED module has four individual emitters of the color green G.

The following combination of individual emitters is used:

| | Rated output of the | Number of | Rated output |
|---|---|---|---|
| Color of | individual emitter in | individual emitters | of a color |
| the LED | Watts (opt.) | (LED) | in Watts (opt.) |
| Red | 3 | 2 | 6 |
| Green | 1.3 | 4 | 5.2 |
| Blue | 2.3 | 2 | 4.6 |
| Turquoise | 1.5 | 2 | 3 |

To generate white of the normal light type D 65, the two LEDs of the color red are modulated at a maximum of 5.08 Watts, the four LEDs with the color green at a maximum of 4.37 Watts, the two LEDs with the color blue at a maximum of 4.47 Watts, as well as the two LEDs of the color turquoise at a maximum of the rated output, or 3 Watts. In this example, turquoise is the color that limits the output.

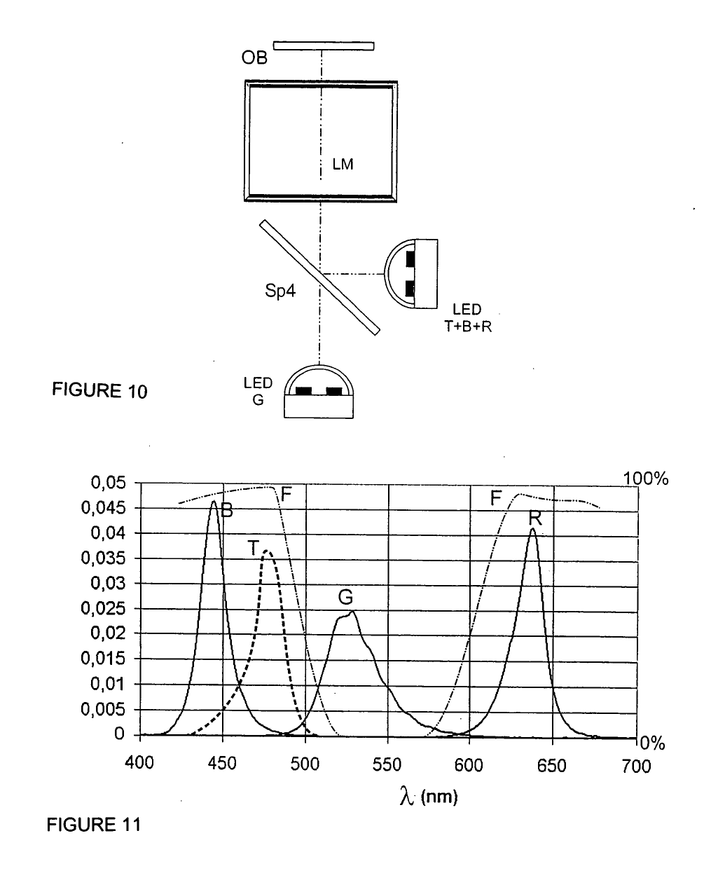

In the example shown in FIG. 10, this two-dimensional array of individual emitters is used in an array for the illumination of an object OK for microscopic observation of the object OK. A light mixing rod LM between the dichroitic beam splitter Sp4 and the object OB is used to homogenize the illumination distribution on the object OB.

FIG. 11 shows the spectral intensities of the light sources for red, green, turquoise and blue. The band-pass characteristic F of the dichroitic beam splitter Sp4 is also shown. In this example, the short-wave band edge of the beam splitter lies between the focal point wavelengths of the turquoise individual emitter LED T and the green individual emitter LED G.

List of Reference Symbols

R red
G green
B blue
T turquoise
LED luminescent diode
LA lens array
KL condenser lens
DMD DMD array
FL field lens
OK projection lens
OB object
LM light mixing rod
Sp 1 dichroitic mirror
Sp 2 dichroitic mirror
Sp 3 splitter mirror
Sp 4 dichroitic mirror
F transmission curve of the dichroitic filter (band-pass characteristic)

1. An array for illuminating an object comprising:
an array of individual emitters, the individual emitters comprising
a first set of individual emitters whose light output focal point wavelength corresponds to red,
a second set of individual emitters whose light output focal point wavelength corresponds to blue,
a third set of individual emitters whose light output focal point wavelength corresponds to green;
an apparatus for spatial superimposition of the red, blue and green light outputs comprising a beam splitter wherein the individual emitters are grouped into a first two dimensional array and a second two dimensional array, the first two dimensional array including red emitters and blue emitters and the second two dimensional array including green emitters and wherein the red, blue and green light outputs are combined such that the spatially superimposed red, blue and green light output produce white illumination light.

2. The array as recited in claim 1, wherein at least one of the first two dimensional array and the second two dimensional array comprises organic light emitting diodes, luminous diodes, luminescent diodes, laser diodes or a combination of the foregoing.

3. The array as recited in claim 1, wherein the first two dimensional array and the second two dimensional array are configured as a first module and a second module wherein the first module comprises at least one green individual emitter and the second module includes at least one blue individual emitter and at least one red individual emitter.

4. The array as recited in claim 3, wherein the first module comprises four green individual emitters and the second module comprises two blue individual emitters and two red individual emitters.

5. The array as recited in claim 1, wherein at least one of the first two dimensional array and the second two dimensional array comprises a fourth set of individual emitters whose light output focal point wavelength corresponds to the color turquoise.

6. The array as recited in claim 1, wherein at least one of the first two dimensional array and the second two dimensional array comprises a fourth set of individual emitters whose light output focal point wavelength is about four hundred eighty eight nanometers.

7. The array as recited in claim 1, wherein the beam splitter comprises a dichroitic beam splitter.

8. The array as recited in claim 1, wherein the beam splitter comprises a polarizing beam splitter.

9. The array as recited in claim 1, wherein the light output of one of the first, second or third sets of individual emitters limits total light output and the limiting light output is combined through a reflective side of a dichroitic beam splitter.

10. A method of illuminating an object, the method comprising the steps of:
creating an array of individual emitters;
selecting the individual emitters to include
a first set of individual emitters whose light output focal point wavelength corresponds to red,
a second set of individual emitters whose light output focal point wavelength corresponds to blue,
a third set of individual emitters whose light output focal point wavelength corresponds to green;
combining the light outputs of the first second and third set of individual emitters with a beam splitter; and
grouping the individual emitters into a first two dimensional array and a second two dimensional array, the first two dimensional array including red emitters and blue emitters and the second two dimensional array including green emitters and wherein the red, blue and green light outputs are combined such that the spatially superimposed red, blue and green light output produce white illumination light.

11. The method as recited in claim 10, further comprising the step of selecting at least one of the first two dimensional array or the second two dimensional array to comprise organic light emitting diodes, luminous diodes, luminescent diodes, laser diodes or a combination of the foregoing.

12. The method as recited in claim 10, further comprising the step of configuring the first two dimensional array and the second two dimensional array to include a first module and a second module wherein the first module comprises at least one green individual emitter and the second module includes at least one blue individual emitter and at least one red individual emitter.

13. The method as recited in claim 12, further comprising the step of configuring the first module and a second module such that the first module comprises four green individual emitters and the second module comprises two blue individual emitters and two red individual emitters.

14. The method as recited in claim 10, further comprising the step of, including a fourth set of individual emitters whose light output focal point wavelength corresponds to turquoise.

15. The method as recited in claim 11, further comprising the step of, including a fourth set of individual emitters whose light output focal point wavelength is about four hundred eighty eight nanometers.

16. The method as recited in claim 10, wherein the beam splitter comprises a dichroitic beam splitter.

17. The method as recited in claim 10, wherein the beam splitter comprises a polarizing beam splitter.

18. The method as recited in claim 10, further comprising the step of directing the light output of one of the first, second or third sets of individual emitters which limits total light output such that the limiting light output is combined through a reflective side of a dichroitic beam splitter.
